(19) United States
(12) Patent Application Publication
(10) Pub. No.: US 2016/0260815 A1
(43) Pub. Date: Sep. 8, 2016

(54) NON-VOLATILE SEMICONDUCTOR MEMORY DEVICE AND METHOD OF MANUFACTURING THE SAME

(71) Applicant: KABUSHIKI KAISHA TOSHIBA, Minato-ku (JP)

(72) Inventor: Ryuji OHBA, Yokkaichi (JP)

(73) Assignee: KABUSHIKI KAISHA TOSHIBA, Minato-ku (JP)

(21) Appl. No.: 14/847,056

(22) Filed: Sep. 8, 2015

Related U.S. Application Data
(60) Provisional application No. 62/129,301, filed on Mar. 6, 2015.

(51) Int. Cl. H01L 29/423; H01L 29/66; H01L 21/28; H01L 27/115

(52) U.S. Cl. CPC H01L 29/42324; H01L 27/11521; H01L 29/66825; H01L 21/28273

(57) ABSTRACT

A non-volatile semiconductor memory device has a plurality of semiconductor areas that are arranged at intervals in a first direction on a semiconductor substrate and extend in a second direction crossing the first direction, a gate insulating layer that is arranged on the semiconductor areas, a charge accumulation layer that is arranged on the gate insulating layer and repeats one time or more a width change where a width of the first direction decreases monotonously, increases thereafter, and decreases again, upward from the gate insulating layer, an inter-electrode insulating layer that is arranged on the charge accumulation layer and covers at least a part of a surface of the charge accumulation layer, and a control electrode that is arranged on the inter-electrode insulating layer.

### CROSS REFERENCE TO RELATED APPLICATIONS

This application is based upon and claims the benefit of priority from the prior U.S. Provisional Patent Application No. 62/129,301 filed on Mar. 6, 2015, the entire contents of which are incorporated herein by reference.

### FIELD

The present invention relates to a non-volatile semiconductor memory device and a method of manufacturing the same.

### BACKGROUND

In a NAND-type flash memory, because a request for a large capacity is high, research and development to progress miniaturization and increase a degree of integration have been progressed.

When memory cells are formed to have a flat cell structure for ,miniaturization, a facing area of a floating gate electrode and a control gate electrode decreases and a sufficient coupling ratio cannot be secured.

If a pitch between the memory cells having the memory cell structure is narrowed, interference between adjacent cells in which a threshold value changes between a plurality of memory cells adjacent to each other in a row direction occurs.

### BRIEF DESCRIPTION OF THE DRAWINGS

FIG. 1 is a plan view of a memory cell array in a NAND-type flash memory;

FIG. 2 is a cross-sectional view taken along the line II-II of

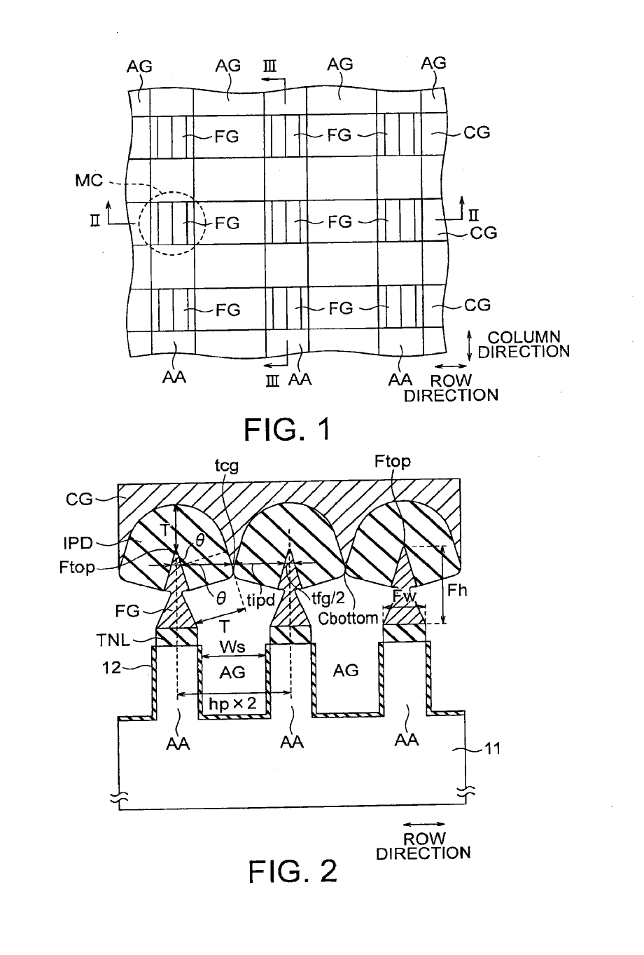

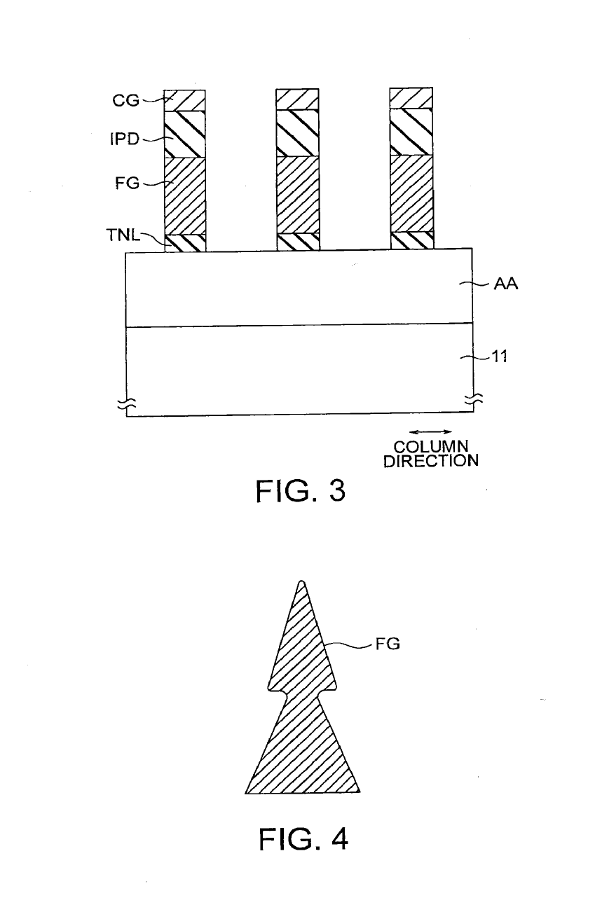

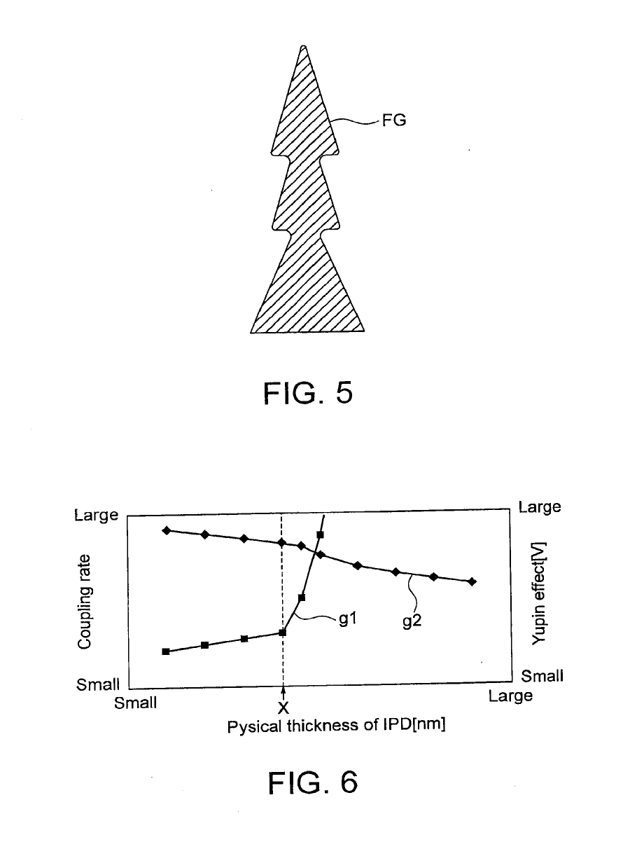

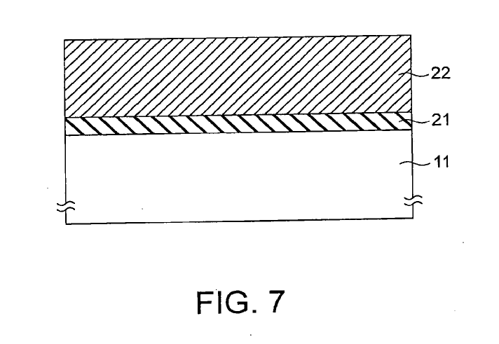

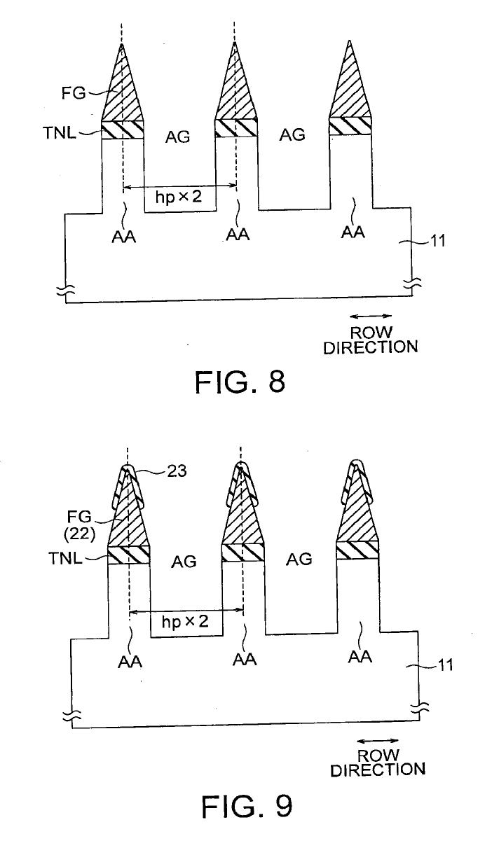

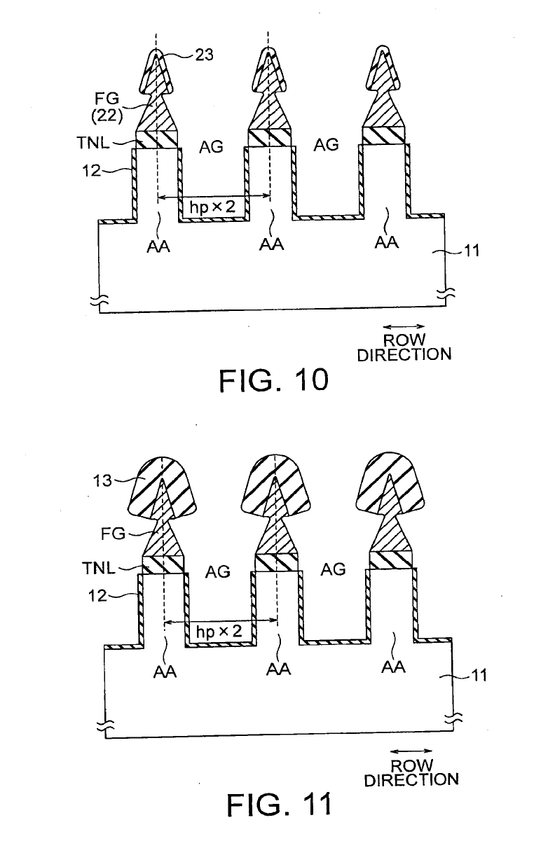

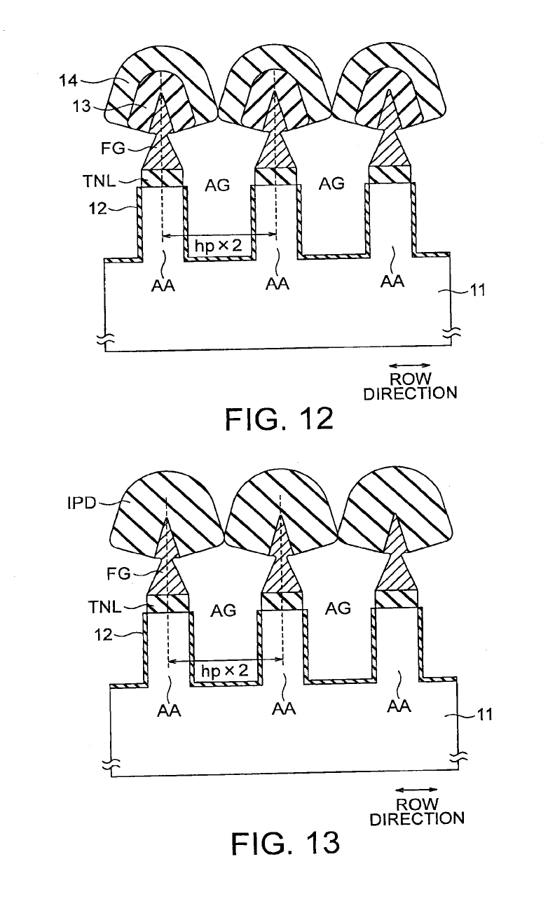

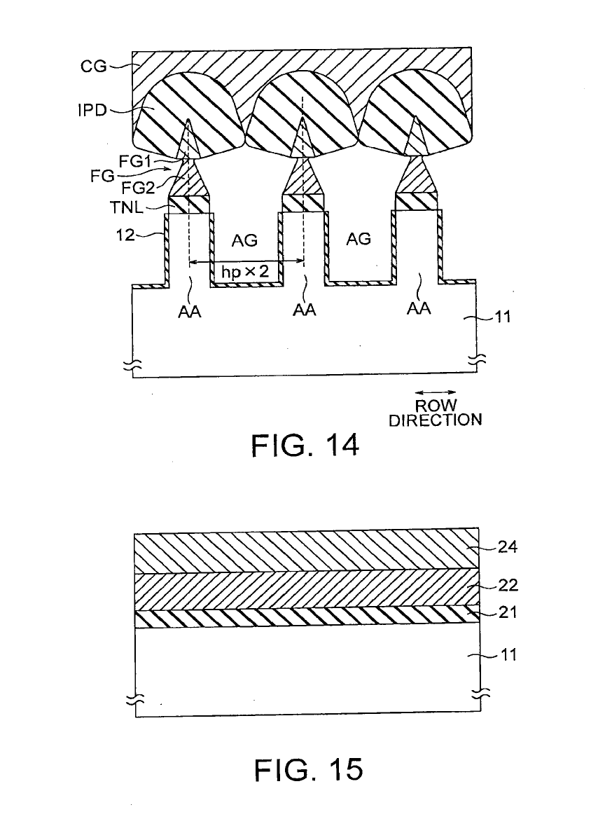

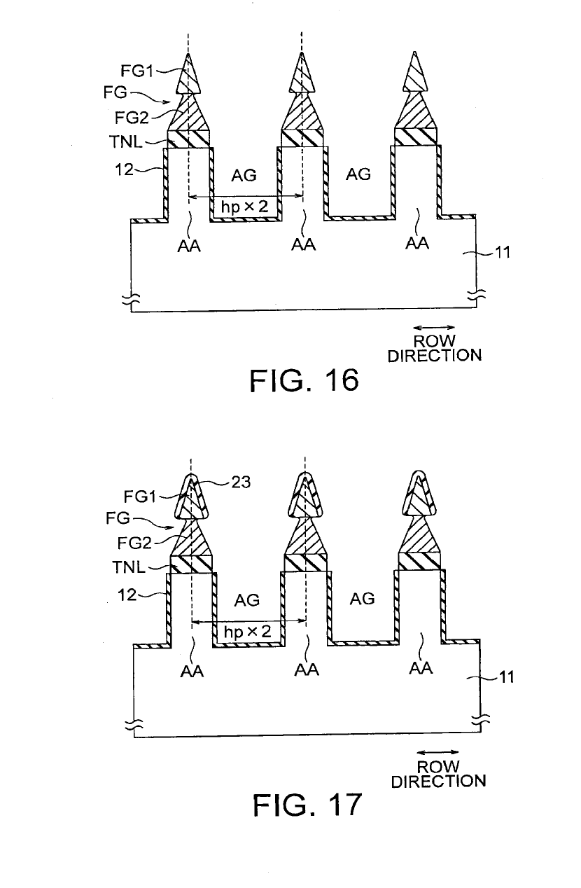

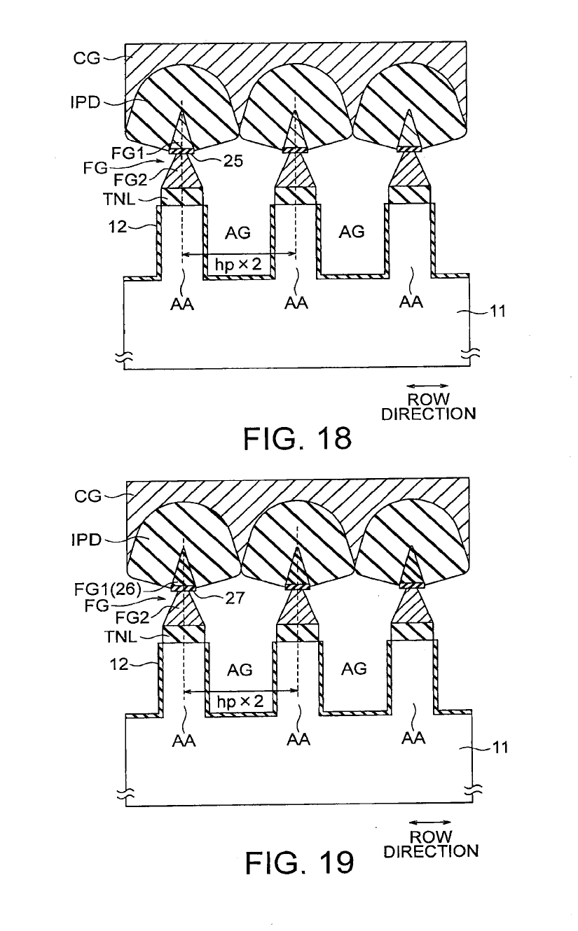

FIG. 1;

FIG. 3 is a cross-sectional view taken along the line of FIG. 1;

FIG. 4 is an enlarged cross-sectional view of a floating gate electrode FG of a two-step taper structure;

FIG. 5 is an enlarged cross-sectional view of a floating gate electrode FG of a three-step taper structure;

FIG. 6 is a graph illustrating a relation of a thickness of an inter-electrode insulating layer and a coupling ratio and interference between adjacent cells;

FIG. 7 is a cross-sectional view illustrating laminated films for a floating gate electrode;

FIG. 8 is a cross-sectional view illustrating a state in which a polysilicon layer is processed in a tapered shape;

FIG. 9 is a cross-sectional view illustrating an example of the case in which an insulating layer is formed on a tapered polysilicon layer;

FIG. 10 is a cross-sectional view illustrating a state in which a polysilicon layer is etched;

FIG. 11 is a cross-sectional view illustrating an example of the case in which an insulating layer 13 is arranged on a lateral surface of a floating gate electrode;

FIG. 12 is a cross-sectional view illustrating an example of the case in which an insulating layer 14 is arranged on the insulating layer 13 on the floating gate electrode;

FIG. 13 is a cross-sectional view illustrating an example of the case in which an inter-electrode insulating layer is formed in the two insulating layers 13 and 14;

FIG. 14 is a cross-sectional view of an array structure having a floating gate electrode FG according to a first modification;

FIGS. 15 and 16 are diagrams illustrating a method of manufacturing the array structure of FIG. 14;

FIG. 17 is a cross-sectional view illustrating an example of the case in which an upper portion side of a polysilicon layer is covered with an oxidation layer and a floating gate electrode is formed;

FIG. 18 is a cross-sectional view illustrating an example of the case in which an insulating layer is arranged between an upper-step tapered portion and a lower-step tapered portion;

FIG. 19 is a cross-sectional view illustrating an example of the case in which a charge trap layer is provided, instead of a metal layer;

FIG. 20 is a cross-sectional view illustrating an example of the case in which a surface of a floating gate electrode is covered with a metal layer;

FIG. 21 is a cross-sectional view illustrating an example of the case in which an insulating layer is arranged between the metal layer and the floating gate electrode of FIG. 20;

FIG. 22 is a cross-sectional view illustrating an example of the case in which an inter-electrode insulating layer is formed in a lower-step tapered portion;

FIG. 23 is a cross-sectional view illustrating an example of the case in which an inter-electrode insulating layer is provided to a lowermost-step tapered portion of a floating gate electrode of a three-step structure;

FIG. 24 is a cross-sectional view illustrating an example of the case in which a base portion is provided in a floating gate electrode;

FIG. 25 is a cross-sectional view illustrating an example of the case in which taper processing is executed from a part of a gate insulating layer; and

FIG. 26 is a cross-sectional view Illustrating an example of the case in which two inter-electrode insulating layers adjacent to each other in a row direction do not contact.

### DETAILED DESCRIPTION

A non-volatile semiconductor memory device according to one embodiment has a plurality of semiconductor areas that are arranged at intervals in a first direction on a semiconductor substrate and extend in a second direction crossing the first direction, a gate insulating layer that is arranged on the semiconductor areas, a charge accumulation layer that is arranged on the gate insulating layer and repeats one time or more a width change where a width of the first direction decreases monotonously, increases thereafter, and decreases again, upward from the gate insulating layer, an inter-electrode insulating layer that is arranged on the charge accumulation layer and covers at least a part of a surface of the charge accumulation layer, and a control electrode that is arranged on the inter-electrode insulating layer. An embodiment of the present invention will be described hereinafter with reference to the drawings. A NAND-type flash memory will be described as an example of a non-volatile semiconductor memory device.

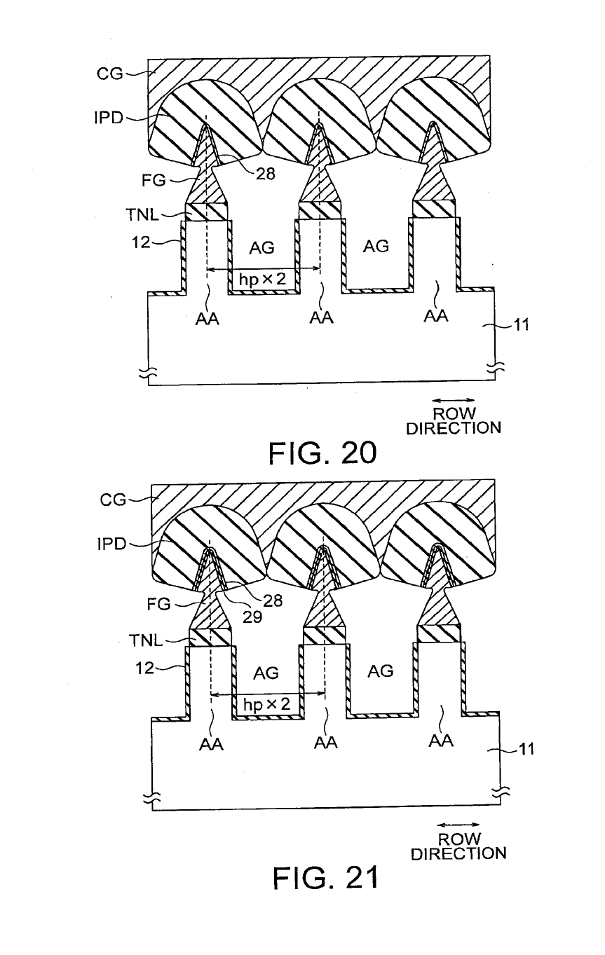

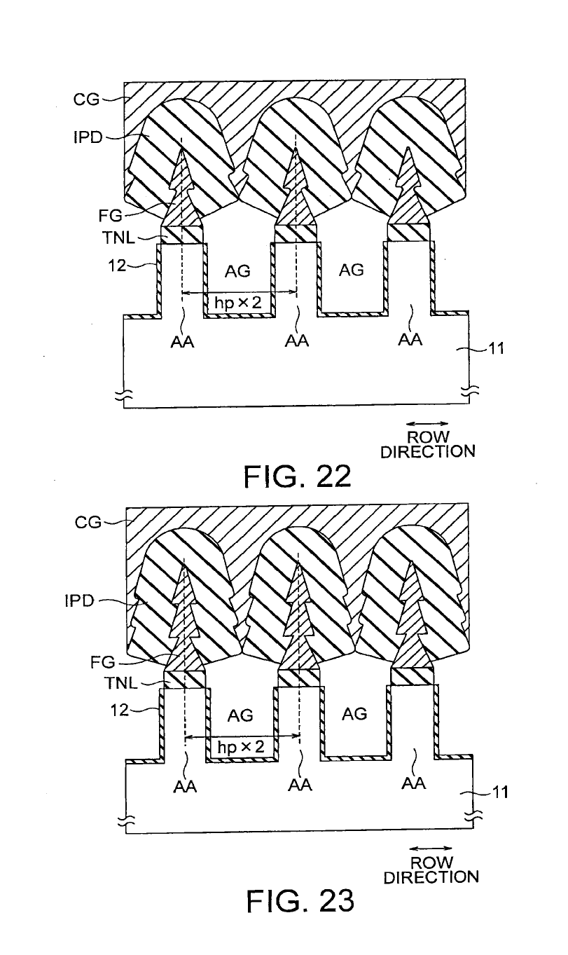

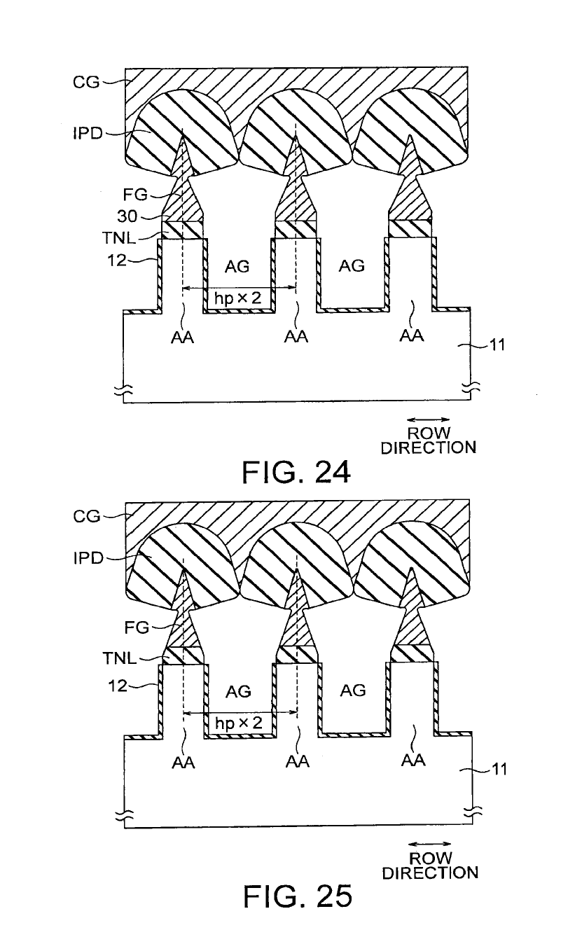

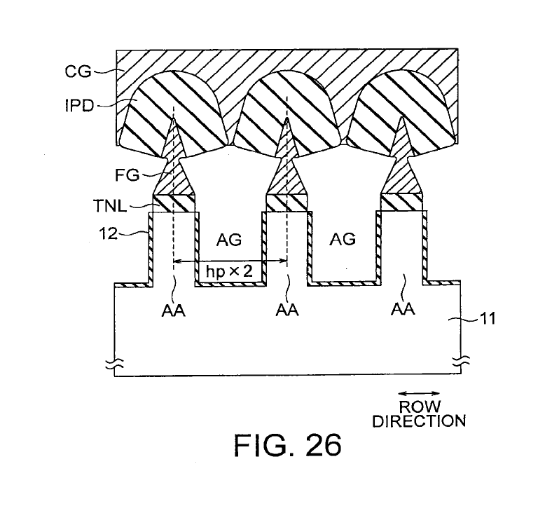

FIG. 1 is a plan view of a memory cell array in the NAND-type flash memory, FIG. 2 is a cross-sectional view taken along the line II-II of FIG. 1, and FIG. 3 is a cross-sectional view taken along the line of FIG. 1.

A semiconductor substrate 11 is a silicon substrate, for example. A top surface of the silicon substrate 11 has an uneven shape. Each of a plurality of convex portions in the uneven shape is a fin-type active area (fin-type semiconductor area) AA. Each fin-type active area AA is arranged in a row direction (first direction) and extends in a column direction (second direction) orthogonal to the row direction. An air gap AG is provided between the two fin-type active areas AA adjacent to each other in the row direction.

The top surface (bottom surfaces of a plurality of concave portions) of the semiconductor substrate 11 and lateral surfaces of the plurality of fin-type active areas AA may be covered with an insulating layer 12. The insulating layer 12 is an oxidation layer formed by oxidizing the semiconductor substrate 11, for example. The insulating layer 12 prevents electrons in the fin-type active area (channel) AA from moving to the air gap AG.

In this embodiment, the plurality of fin-type active areas AA are a part of the semiconductor substrate 11. However, the present invention is not limited thereto. For example, the plurality of fin-type active areas AA may be a semiconductor layer such as an epitaxial layer on the semiconductor substrate 11.

On each fin-type active area AA, a plurality of memory cells (field effect transistors: FET) MC are arranged in the column direction. The plurality of memory cells MC on one fin-type active area AA are connected in series in the column direction to configure a NAND string. A plurality of bit lines (not illustrated in the drawings) are arranged in a direction crossing each fin-type active area AA, that is, the column direction.

Each memory cell MC includes a gate insulating layer (tunnel insulating layer) TNL on the fin-type active area AA, a floating gate electrode FG on the gate insulating layer TNL, an inter-electrode insulating layer (Inter-Poly Dielectrics) IPD on the floating gate electrode FG, and a control gate electrode CG on the inter-electrode insulating layer IPD.

The gate insulating layer TNL is a silicon oxide layer, for example, and is formed by oxidizing the top surface of the fin-type active area AA.

The floating gate electrode FG is a polysilicon layer, a metal layer, or a laminate thereof, for example. During lamination, an insulating layer may be included. A cross-section obtained by cutting the floating gate electrode FG along the row direction repeats one time or more a width change where a width of the row direction decreases monotonously, increases thereafter, and decreases again, in an upward direction. That is, the floating gate electrode FG has a cross-section in which the width of the row direction is minimized between the top surface and the bottom surface of the floating gate electrode FG. For this reason, the cross-section of the row direction of the floating gate electrode FG has a shape in which triangles and trapezoids are overlapped in a plurality of steps in a vertical direction. Hereinafter, each step of the floating gate electrode FG is called a tapered portion. For example, in the case of the floating gate electrode FG having a structure in which triangles and trapezoids are overlapped in two steps in a vertical direction, in the cross-section of the row direction, an upper step is called an upper-step tapered portion FG1 and a lower step is called a lower-step tapered portion FG2.

Because the floating gate electrode FG is processed by etching, to be exact, a corner portion is rounded as illustrated by an enlarged view of FIG. 4. A tip portion of the floating gate electrode FG may be flat. The floating gate electrode FG is not limited to the two-step structure and may have a three-step structure illustrated in FIG. 5, or may have a structure of four steps or more. The cross-section of the row direction of the floating gate electrode according to this embodiment may have a shape (for example, semi-circles) in which the width of the row direction decreases monotonously in an upward direction are overlapped in a plurality of steps in the vertical direction, in addition to the structure in which the triangles or the trapezoids are overlapped in the plurality of steps in the vertical direction.

In FIGS. 4 and 5, as for the width of the row direction of the tapered portion of each step of the floating gate electrode FG in which the plurality of tapered portions are vertically laminated, the widths of the lower tapered portions increase, the width of the row direction of the lowermost-step tapered portion is maximum, and the width of the row direction of the uppermost-step tapered portion is minimum.

As such, if the tapered portions of which the width of the row direction decreases monotonously in the upward direction are overlapped in the two steps in the vertical direction, the width of the row direction decreases in the middle of the vertical direction.

As a result, an interval between the two floating gate electrodes FG adjacent to each other in the row direction increases in the middle of the vertical direction and a suppression effect of interference between adjacent cells becomes high. In other words, even though an interval (half pitch) between the active areas AA in the row direction is narrowed, cavities are formed in the floating gate electrodes FG. For this reason, the interval between the floating gate electrodes FG is not narrowed, thereby realizing miniaturization.

The lateral surface of the row direction of the floating gate electrode FG may be covered with an insulating layer such as an oxidation layer. In this case, the insulating layer covering the lateral surface of the row direction of the floating gate electrode FG prevents electrons accumulated in the floating gate electrode FG from moving to the air gap AG.

The inter-electrode insulating layer IPD covers at least a part of the surface of the floating gate electrode FG. In this embodiment, the floating gate electrode FG is formed to have a taper structure of a plurality of steps in a vertical direction, so that the inter-electrode insulating layer IPD does not cover the lower portion of the floating gate electrode FG. As a result, the thickness of the inter-electrode insulating layer IPD between the two floating gate electrodes FG adjacent to each other in the row direction can be reduced and a suppression effect of the interference between the adjacent cells can be improved.

That is, in the floating gate electrode FG of FIG. 2, the upper-step tapered portion FG1 is arranged on the lower-step tapered portion FG2. For this reason, when the inter-electrode insulating layer IPD is formed on the surface of the tapered portion using a sputtering method and a CVD method, the inter-electrode insulating layer IPD is hard to be adhered to the lower-step tapered portion FG2 due to the upper-step tapered portion FG1. As such, the floating gate electrode FG is formed to have the tapered portions of the plurality of steps, so that it is easy to control an arrangement place of the inter-electrode insulating layer IPD. Therefore, in a place where it is easy to cause the interference between the adjacent cells, it is possible to make it difficult to form the inter-electrode insulating layer IPD and it is hard to be affected by the interference between the adjacent cells.

The inter-electrode insulating layer IPD includes a high dielectric constant material (High-k material) having a dielectric constant higher than a dielectric constant of a silicon oxide layer to improve a coupling ratio of the memory cells. For example, the high dielectric constant material is a metal oxide such as AlO, Al₂O₃, ZrO₂, ZrSiO, HfO, HfO₂, HfSiO, HfAlO, LaAlO(LAO), and LaAlSiO(LASO) or a laminate thereof. In addition, the high dielectric constant material may be a laminate of a silicon oxide layer such as ONO and a silicon nitride layer.

When the floating gate electrode FG and the control gate electrode CG include a polysilicon layer, the inter-electrode insulating layer IPD is called an inter-polysilicon dielectric (IPD).

The control gate electrode CG includes a polysilicon layer, a metal silicide layer, or a laminate thereof. The control gate electrode CG and the inter-electrode insulating layer IPD extend in the column direction. The control gate electrode CG configures a word line.

In the array structure described above, the two inter-electrode insulating layers IPD of the two memory cells adjacent to each other in the row direction have a contact portion in which both the inter-electrode insulating layers contact each other. The thickness (in this embodiment, 0 or almost 0) of a vertical direction (third direction) orthogonal to the row direction and the column direction of the two inter-electrode insulating layers IPD in the contact portion is smaller than the thickness T of the vertical direction of the two inter-electrode insulating layers IPD in top portions Ftop of the two floating gate electrodes FG of the two memory cells adjacent to each other in the row direction.

As a result, the control gate electrode CG has a bottom portion Cbottom in the contact portion of the two inter-electrode insulating layers IPD. The bottom portion Cbottom is located at an approximately center portion of a gap between the two floating gate electrodes FG adjacent to each other in the row direction. In addition, the bottom portion Cbottom of the control gate electrode CG is formed below the top portion Ftop of the floating gate electrode FG.

Therefore, according to this array structure, the inter-electrode insulating layer IPD and the control gate electrode CG can be partially inserted between the two floating gate electrodes FG adjacent to each other in the row direction. As a result, because a facing portion of the floating gate electrode FG and the control gate electrode CG increases, a coupling ratio of the memory cells MC can be improved. In addition to the inter-electrode insulating layer IPD, the control gate electrode CG is inserted between the two floating gate electrodes FG adjacent to each other in the row direction, so that the thickness of the inter-electrode insulating layer IPD can be reduced, and the interference between the adjacent cells can be suppressed.

FIG. 6 is a graph illustrating a relation of the thickness of the inter-electrode insulating layer IPD and the coupling ratio and the interference between the adjacent cells. In FIG. 6, a horizontal axis shows the thickness [nm] of the inter-electrode insulating layer IPD, a left vertical axis shows the coupling ratio, and a right vertical axis shows a Yupin effect [V] showing the interference between the adjacent cells. In FIG. 6, a graph g1 shows the Yupin effect when the inter-electrode insulating layer IPD changes and a graph g2 shows the coupling ratio when the inter-electrode insulating layer IPD changes.

As known from the graph g1, if the thickness of the inter-electrode insulating layer IPD is more than a predetermined value X, the interference between the adjacent cells (Yupin effect) rapidly increases. Meanwhile, if the inter-electrode insulating layer IPD increases, the coupling ratio gradually decreases.

As known from a result of FIG. 6, if the thickness of the inter-electrode insulating layer IPD existing between the two floating gate electrodes FG adjacent to each other in the row direction increases excessively, it is easy to cause the interference between the adjacent cells. Therefore, in this embodiment, the thickness of a contact position between the inter-electrode insulating layers IPD arranged around the two floating gate electrodes FG adjacent to each other in the row direction is approximately 0 ideally and the control gate electrode CG is arranged in the vicinity of the contact position of the inter-electrode insulating layer IPD. As a result, the coupling ratio can be improved by the control gate electrode CG while the thickness of the inter-electrode insulating layer IPD between the two floating gate electrodes FG adjacent to each other in the row direction is limited.

In this embodiment, similar to the flat cell structure, there is no likelihood to impair an effect in that the half pitch hp to be the half of the pitch of the active area AA is not limited by the inter-electrode insulating layer IPD and the control gate electrode CG. This will be explained specifically.

When the half of a distance (pitch of the active area AA) from the center of one active area AA to the center of another active area AA adjacent to one active area AA is set to the half pitch hp, the half pitch hp can be represented by

hp=(tfg+tcg)/2+tipd (1).

However, when a virtual line passing through the floating gate electrode FG in the portion (upper portion) covered with the inter-electrode insulating layer IPD and extending in the row direction is assumed, tfg is a width of the row direction of the floating gate electrode FG on the virtual line, tcg is a width of the row direction of the control gate electrode CG on the virtual line, and tipd is a width of the row direction of the inter-electrode insulating layer IPD on the virtual line.

When the thickness of the inter-electrode insulating layer IPD in a direction vertical to the lateral surface of the floating gate electrode FG in the row direction is set to T, T and tipd have a relation of

tipd=T/cos θ (2).

tipd is almost constant without depending on a position, but tfg and tcg change according to the position. In addition, tfg and tcg have a complementary relation. If tfg increases, tcg decreases and if tfg decreases, tcg increases.

That is, according to this embodiment, though the inter-electrode insulating layer IPD and the control gate electrode CG are partially inserted between the two floating gate electrodes FG, the half pitch hp is not limited by the inter-electrode insulating layer IPD and the control gate electrode CG.

The half pitch hp corresponds to the half of a pitch of bit lines (not illustrated in the drawings) arranged on the upper portion of the active area AA.

In addition, according to this embodiment, because the half pitch hp is not limited by the inter-electrode insulating layer IPD and the control gate electrode CG, the thickness tipd of the row direction of the inter-electrode insulating layer IPD in the lateral surface of the floating gate electrode FG in the row direction can be set to be larger than the half of a space Ws of the row direction between the fin-type active areas AA.

Meanwhile, in a conventional structure in which the inter-electrode insulating layer IPD and the control gate electrode CG are inserted between the two floating gate electrodes FG, because the control gate electrode CG having the constant thickness should be inserted into in a constant space between the two floating gate electrodes FG, the thickness of the row direction of the inter-electrode insulating layer IPD cannot be set to be larger than the half of the space Ws of the row direction between the fin-type active areas AA.

In this embodiment, a portion between the plurality of floating gate electrodes FG is the air gap. However, the air gap can be replaced with an insulating layer (for example, a silicon oxide layer) of which a relative dielectric constant is smaller than a relative dielectric constant of the inter-electrode insulating layer IPD. In addition, in this embodiment, a charge accumulation layer of the memory cell MC is the floating gate electrode FG. However, the floating gate electrode FG can be replaced with a charge trap layer (insulating layer) having a function of trapping charges.

In addition, in this embodiment, the plurality of memory cells MC arranged in the column direction do not have a diffusion layer in the fin-type active area AA. The reason is as follows. If each memory cell MC is miniaturized, a channel can be formed in the fin-type active area AA by a so-called fringe effect, even though the diffusion layer does not exist.

However, each memory cell MC may have the diffusion layer in the fin-type active area AA.

According to the array structure according to this embodiment, an increase of the coupling ratio and prevention of the interference between the adjacent cells can be realized at the same time.

Next, a method of manufacturing the cell array structure according to this embodiment will be explained below.

First, as illustrated in FIG. 7, the insulating layer 21 to form the gate insulating layer TNL and the polysilicon layer 22 to form the floating gate electrode FG are laminated sequentially on the semiconductor substrate 11. The insulating layer 21 is a silicon oxide layer, for example.

Next, a photoresist layer (not illustrated in the drawings) is formed on the polysilicon layer 22 by lithography. The photoresist layer has line & space patterns that are arranged in the row direction at a constant pitch and extend in the column direction.

Next, the polysilicon layer 22 is patterned by reactive ion etching (RIE), using the photoresist layer as a mask. Next, the photoresist layer is removed. Next, the insulating layer 21 and the semiconductor substrate 11 are etched by dry etching, using the patterned polysilicon layer 22 as a mask.

As a result, as illustrated in FIG. 8, the active areas AA having the line & space patterns that are arranged in the row direction at the constant pitch (half pitch hp x 2) and extend in the column direction are formed. The polysilicon layer 22 is etched by the dry etching such that the tip end side is etched more and a shape of the polysilicon layer 22 becomes a tapered shape in which the width <of the row direction is narrowed in an upward direction.

Instead of the above process, the polysilicon layer 22, the insulating layer 21, and the semiconductor substrate 11 may be continuously etched by the RIE, using the photoresist layer as the mask. In this case, after the etching, dry etching and wet etching to form the polysilicon layer 22 in the tapered shape are performed.

Next, as illustrated in FIG. 9, an insulating layer 23 such as a thin oxidation layer is formed on only the upper portion of the polysilicon layer 22 of the tapered shape, using a film forming method such as the CVD method having poor coverage characteristics.

Next, as illustrated in FIG. 10, the polysilicon layer 22 is partially etched by the dry etching, using the insulating layer 23 as a mask. By performing the dry etching, an upper portion side of the polysilicon layer 22 not covered with the insulating layer 23 is etched more. As a result, a portion of the polysilicon layer 22 not covered with the insulating layer 23 is tapered.

Instead of the dry etching, the wet etching may be performed and the polysilicon layer 22 not covered with the insulating layer 23 may be tapered. In this case, because an etching target is the polysilicon layer 22, nitric acid and KOH are used as an etchant for the wet etching.

Next, the insulating layer 23 adhered to the upper portion of the polysilicon layer 22 is removed and the floating gate electrode FG of a structure in which tapered shapes are overlapped in two steps in a vertical direction (hereinafter, referred to as a two-step taper structure) is finished.

Next, the entire surface of the semiconductor substrate 11 is covered with the insulating layer 12. The insulating layer 12 may be a natural oxidation layer. In addition, the surface of the floating gate electrode FG may be covered with an insulating layer such as the natural oxidation layer.

Next, as illustrated in FIG. 11, the insulating layer (for example, a silicon oxide layer) 13 is formed on only the upper portion of the floating gate electrode FG, using a film forming method such as the sputtering method and the CVD method having poor coverage characteristics. Because the floating gate electrode FG has the two-step taper structure, gas is hard to move to the lower-step tapered portion FG2 and the insulating layer 13 is formed in only the upper-step tapered portion FG1.

Next, as illustrated in FIG. 12, an insulating layer (for example, a lanthanum aluminate layer) 14 is formed on only the insulating layer 13 of the upper portion of the floating gate electrode FG, using a film forming method such as the sputtering method and the CVD method having poor coverage characteristics.

Even in this case, because the gas is hard to move to the lower-step tapered portion FG2, the insulating layer 14 is formed on only the insulating layer formed in FIG. 11.

In addition, heat treatment is performed to cause the two insulating layers 13 and 14 to react with each other and as illustrated in FIG. 13, one insulating layer (for example, a lanthanum aluminate layer) functioning as the inter-electrode insulating layer IPD is formed. Then, as illustrated in FIG. 2, the control gate electrode CG is formed on the inter-electrode insulating layer IPD. The control gate electrode CG is formed by the following process, for example.

An electrode material is formed on the inter-electrode insulating layer IPD and a mask layer is formed on the electrode material. The mask layer has the line & space patterns that are arranged in the column direction (front-to-rear direction of a plane of paper of FIG. 2) at a constant pitch and extend in the row direction.

In addition, each of the electrode material and the inter-electrode insulating layer IPD is patterned by the RIE, using the mask layer. At this time, the floating gate electrode FG existing in an area not covered with the mask layer is also etched.

That is, the floating gate electrodes FG of the plurality of memory cells that are connected in series in the column direction are separated from each other.

Here, the mask layer is a hard mask layer to execute a sidewall patterning process (double patterning process), for example. This process is known as technology for realizing a narrow line width or a narrow line pitch.

The cell array structure of FIG. 2 is finished by the manufacturing method described above.

### First Modification

The entire portion of the floating gate electrode FG of the two-step taper structure in this embodiment may not be formed of the same material. For example, the upper-step tapered portion FG1 and the lower-step tapered portion FG2 of the floating gate electrode FG may be formed of different materials.

FIG. 14 is a cross-sectional view of an array structure having a floating gate electrode FG according to a first modification. In the floating gate electrode FG of FIG. 14, an upper-step tapered portion FG1 is formed of a metal layer and a lower-step tapered portion FG2 is formed of the same polysilicon layer as that in FIG. 2. The metal layer of the upper-step tapered portion FG1 contains a metal or a metal compound having superior electron accumulation efficiency, such as Ru, TiN, TaN, and WSi.

Generally, the metal has a property that the metal diffuses when heat is applied. For this reason, it is preferable to form the upper-step tapered portion FG1 rather than the lower-step tapered portion FG2 using the metal layer. This is because the metal may partially diffuse in the gate insulating layer TNL, when the lower-step tapered portion FG2 is formed of the metal layer.

FIGS. 15 and 16 are diagrams illustrating a method of manufacturing the array structure of FIG. 14. First, as illustrated in FIG. 15, the insulating layer 21 to form the gate insulating layer TNL, the polysilicon layer 22, and a metal layer 24 are laminated sequentially on the semiconductor substrate 11. Next, these laminated films are patterned by the photolithography.

Next, as illustrated in FIG. 16, the floating gate electrode FG of the two-step taper structure is formed by the dry etching. In the dry etching, because an etching rate of the polysilicon layer 22 is more than an etching rate of the metal layer 24, the polysilicon layer 22 is cut more. As a result, the floating gate electrode FG of the two-step taper structure illustrated in FIG. 16 is obtained.

As illustrated in FIG. 17, similar to FIG. 9, the upper portion side of the polysilicon layer 22 is covered with an oxidation layer 23 and the dry etching and the wet etching are executed, so that the floating gate electrode FG of the two-step taper structure can be formed.

As illustrated in FIG. 14, if the upper-step tapered portion FG1 in the floating gate electrode FG is formed of the metal layer, taken electrons can be stably accumulated and the electrons are hard to leak from the upper-step tapered portion FG1 to the inter-electrode insulating layer IPD, because the metal has a large work function. Therefore, according to the structure of FIG. 14, a leak current of a path passing through the inter-electrode insulating layer IPD can be suppressed.

In the floating gate electrode FG of FIG. 14, as illustrated in FIG. 18, an insulating layer 25 may be arranged between the upper-step tapered portion FG1 and the lower-step tapered portion FG2. The insulating layer 25 prevents the metal of the upper-step tapered portion FG1 formed of the metal layer 24 from diffusing in the lower-step tapered portion FG2 and is formed of SiN, for example.

The upper-step tapered portion FG1 of the floating gate electrode FG may be formed of a charge trap layer 26 made of an insulating layer to trap charges, as illustrated in FIG. 19, instead of the metal layer 24 illustrated in FIG. 14. The charge trap layer of FIG. 19 is formed of an insulating layer such as SiN, SiON, Al₂O₃, and HfO.

In FIG. 19, an insulating layer 27 having the thickness of 10 nm or less is arranged between the lower-step tapered portion FG2 formed of the polysilicon layer and the charge trap layer 26 of the upper-step tapered portion FG1. However, the insulating layer 27 may be omitted.

Because the charge trap layer 26 has a function of raising a potential barrier by capturing of the charges, a leak current flowing to the two inter-electrode insulating layers IPD adjacent to each other in the row direction and the column direction can be suppressed.

In FIG. 14, the upper-step tapered portion FG1 of the floating gate electrode FG is formed of the metal layer 24. However, as illustrated in FIG. 20, the entire portion of the floating gate electrode FG may be formed of the polysilicon layer and a surface of a part thereof, for example, a surface of the upper-step tapered portion FG1 may be covered with a thin metal layer 28. In this case, because the electrons can be stably accumulated in the thin metal layer 28, the leak current flowing to the inter-electrode insulating layer IPD can be suppressed, similar to FIG. 14.

As illustrated in FIG. 21, a thin insulating layer 29 such as SIN may be inserted between the thin metal layer 28 and the polysilicon layer.

### Second Modification

In the embodiment, the inter-electrode insulating layer IPD is arranged on only the upper-step tapered portion FG1 of the floating gate electrode FG of the two-step taper structure. However, as illustrated in FIG. 22, the inter-electrode insulating layer IPD may be arranged on the lower-step tapered portion FG2. For example, gas is moved to the lower side by a CVD device, so that the inter-electrode insulating layer IPD can be formed in the lower-step tapered portion FG2, as illustrated in FIG, 22. However, the inter-electrode insulating layer IPD is hard to be adhered to the lower-step tapered portion FG2, because the upper-step tapered portion FG1 exists. Therefore, the thickness of the inter-electrode insulating layer IPD arranged on the lower-step tapered portion FG2 is set to be smaller than the thickness of the inter-electrode insulating layer IPD arranged on the upper-step tapered portion FG1.

In the case of a structure of FIG. 22, the two inter-electrode insulating layers IPD arranged in the lower-step taped portions FG2 of the two floating gate electrodes FG adjacent to each other in a row direction contact each other and the two inter-electrode insulating layers IPD arranged in the upper-step tapered portions FG1 do not contact each other. The two inter-electrode insulating layers IPD arranged on the lower-step tapered portion FG2 contact at almost centers of two active areas AA and the thickness of a contact position is minimized. In addition, a control gate electrode CG is arranged to the contact position.

By this structure, in FIG. 22, capacitance between the control gate electrode CG and the floating gate electrode FG can be increased and a coupling ratio can be increased, as compared with the structure of FIG. 2 in which the inter-electrode insulating layer IPD is arranged on only the upper-step tapered portion FG1.

FIG. 23 illustrates an example of the case in which the floating gate electrode FG is formed to have a structure of three steps and the inter-electrode insulating layer IPD is arranged on each of an upper-step tapered portion FG1, an intermediate-step tapered portion FG3, and a lower-step tapered portion FG2. In FIG. 23, the inter-electrode insulating layer IPD arranged on the lower-step tapered portion FG2 is contacted with another inter-electrode insulating layer IPD adjacent in the row direction and the inter-electrode insulating layers IPD adjacent to each other in the row direction are not contacted in the upper-step tapered portion FG1 and the intermediate-step tapered portion FG3. In the structure of FIG. 23, a coupling ratio between the control gate electrode CG and the floating gate electrode FG can be increased as compared with the structure of FIG. 22.

### Third Modification

In each floating gate electrode FG described above, the polysilicon layer is processed in the tapered shape by the etching etc. However, it is difficult to surely process the floating gate electrode FG in the tapered shape, from the interface of the gate insulating layer TNL and the floating gate electrode FG, as illustrated in FIG. 2, for example. For this reason, as illustrated in FIG. 24, a base portion 30 not processed in a tapered shape may be provided as a margin area for taper processing in a lower end portion of the floating gate electrode FG. The floating gate electrode FG of FIG. 24 has the base portion 30 from the interface with the gate insulating layer TNL to a predetermined height. A width of the row direction of the base portion 30 is equal to a width of the gate insulating layer TNL. The floating gate electrode FG is inclined from a top surface of the base portion 30. The height of the base portion 30 is variable due to a manufacture variation.

In addition, when the gate insulating layer TNL can have the larger thickness, as illustrated in FIG. 25, the taper processing may be executed from a part of the gate insulating layer TNL. In FIG. 25, it is not preferable to have the gate insulating layer TNL small in thickness, from the viewpoint of securing a channel in the active area AA. Therefore, the structure of FIG. 24 is more preferable than the structure of FIG. 25.

### Fourth Modification

In the example described above, the two inter-electrode insulating layers IPD adjacent to each other in the row direction contact at the approximately center portion of the interval of the active areas AA. However, as illustrated in FIG. 26, the two inter-electrode insulating layers IPD may not contact each other.

In this case, the control gate electrode CG is arranged between nearest proximity positions of the two inter-electrode insulating layers IPD. In addition, the nearest proximity positions of the two inter-electrode insulating layers IPD are at the height from an uppermost portion to a lowermost portion of the floating gate electrode FG. In addition, the nearest proximity positions of the two inter-electrode insulating layers IPD are at the approximately center portion of the interval of the active areas AA.

As a result, even though the two inter-electrode insulating layers IPD do not contact each other, a coupling ratio can be increased and interference between adjacent cells is hard to occur.

As such, in this embodiment, because the tapered portions of the plurality of steps are provided in the floating gate electrode FG, a width of the row direction in the middle of a vertical direction of the floating gate electrode FG can be narrowed and a substantial distance between the adjacent cells increases. For this reason, the interference between the adjacent cells is hard to occur. Therefore, the interval of the active areas AA can be narrowed and miniaturization is enabled.

In addition, the tapered portions of the plurality of steps are provided in the floating gate electrode FG, so that a position of an end portion of the inter-electrode insulating layer IPD arranged on the surface of the floating gate electrode FG is easily controlled, and the interference between the adjacent cells is suppressed. For example, when the floating gate electrode FG has the upper and lower two tapered portions, control to arrange the inter-electrode insulating layer IPD on only the upper-step tapered portion FG1 can be easily performed and a failure does not occur, where the inter-electrode insulating layer IPD extends to the lower side of the floating gate electrode FG unintentionally, the thickness thereof increases, and the interference between the adjacent cells occurs.

According to this embodiment, because the shape of the inter-electrode insulating layer IPD is easily controlled, a contact position between the two inter-electrode insulating layers IPD arranged in the two floating gate electrodes FG adjacent to each other in the row direction can be set to the approximately center portion between the two floating gate electrodes FG, the height of the contact position between the two inter-electrode insulating layers IPD can be set between an uppermost point to a lowermost point of the floating gate electrode FG, and the thickness of the contact area between the two inter-electrode insulating layers IPD can be minimized. As a result, the interference between the adjacent cells can be suppressed, a coupling ratio of the control gate electrode CG and the floating gate electrode FG can be improved, and electrons of an amount necessary for the floating gate electrode FG can be accumulated, even though miniaturization progresses.

In addition, the different materials are used as the materials of the upper-step tapered portion FG1 and the lower-step tapered portion FG2 in the floating gate electrode FG and the upper-step tapered portion FG1 is configured to contain a metal having a high charge accumulation effect, so that a floating gate electrode FG having high charge accumulation efficiency can be manufactured.

Some embodiments of the present invention have been described. However, the embodiments are only for exemplary purpose and do not limit the scope of the invention. New embodiments can be carried out in a variety of other forms and various omissions, replacements, and changes can be made without departing from the scope of the invention. The embodiments and the modifications are included in the range and the scope of the invention and are included in a range equivalent to the range of the invention.

1. A non-volatile semiconductor memory device comprising:
a plurality of semiconductor areas that are arranged at intervals in a first direction on a semiconductor substrate and extend in a second direction crossing the first direction;
a gate insulating layer that is arranged on the semiconductor areas;
a charge accumulation layer that is arranged on the gate insulating layer and repeats one time or more a width change where a width of the first direction decreases monotonously, increases thereafter, and decreases again, upward from the gate insulating layer;
an inter-electrode insulating layer that is arranged on the charge accumulation layer and covers at least a part of a surface of the charge accumulation layer; and
a control electrode that is arranged on the inter-electrode insulating layer.

2. The non-volatile semiconductor memory device according to claim 1,
wherein the inter-electrode insulating layer covers an upper side of a position where the width of the first direction decreases monotonously and is minimized, or a predetermined position above the position, in the surface of the charge accumulation layer.

3. The non-volatile semiconductor memory device according to claim 1,
wherein the inter-electrode insulating layer covers an upper side of a position where the width of the first direction decreases monotonously and is minimized, or a predetermined position below the position, in the surface of the charge accumulation layer.

4. The non-volatile semiconductor memory device according to claim 3,
wherein a thickness of the inter-electrode insulating layer of a portion below the position where the width is minimized is smaller than a thickness of the inter-electrode insulating layer of a portion on the position where the width is minimized.

5. The non-volatile semiconductor memory device according to claim 1,
wherein two inter-electrode insulating layers adjacent to each other in the first direction contact each other at a position lower than an upper end portion of the charge accumulation layer.

6. The non-volatile semiconductor memory device according to claim 5,
wherein the control electrode is arranged above a position where the two inter-electrode insulating layers contact, the position being a lowermost portion of the control electrode, and
the lowermost portion of the control electrode is arranged below an uppermost portion of the charge accumulation layer.

7. The non-volatile semiconductor memory device according to claim 1,
wherein the control electrode is arranged between nearest proximity positions of two inter-electrode insulating layers adjacent to each other in the first direction, and
the nearest proximity positions are arranged below an uppermost portion of the charge accumulation layer.

8. The non-volatile semiconductor memory device according to claim 1,
wherein the charge accumulation layer is a laminated body obtained by laminating two or more layers made of different materials.

9. The non-volatile semiconductor memory device according to claim 8,
wherein the charge accumulation layer comprises a polysilicon layer and a metal layer arranged on the polysilicon layer, and
a width of the first direction of each of the polysilicon layer and the metal layer decreases monotonously, upward from the gate insulating layer.

10. The non-volatile semiconductor memory device according to claim 9,
wherein an insulating layer is arranged between the polysilicon layer and the metal layer.

11. The non-volatile semiconductor memory device according to claim 8,
wherein the charge accumulation layer comprises a polysilicon layer of a shape in which a width change where a width of the first direction decreases monotonously, increases thereafter, and decreases again is repeated one time or more and a metal layer arranged on at least a part of a surface of the polysilicon layer.

12. The non-volatile semiconductor memory device according to claim 11, further comprising an insulating layer arranged between the polysilicon layer and the metal layer.

13. The non-volatile semiconductor memory device according to claim 1,
wherein a maximum width of the first direction of the side contacting the gate insulating layer in the charge accumulation layer is equal to or larger than a maximum width of the first direction when the width of the first direction decreases monotonously and increases thereafter, upward from the gate insulating layer.

14. A non-volatile semiconductor memory device comprising:
a plurality of semiconductor areas that are arranged at intervals in a first direction on a semiconductor substrate and extend in a second direction crossing the first direction;
a gate insulating layer that is arranged on the semiconductor areas;
a charge accumulation layer that is arranged on the gate insulating layer and has a width of the first direction minimized between a top surface and a bottom surface;
an inter-electrode insulating layer that is arranged on the charge accumulation layer and covers at least a part of a surface of the charge accumulation layer; and
a control electrode that is arranged on the inter-electrode insulating layer.

15. A method of manufacturing a semiconductor memory device, comprising:
forming a plurality of semiconductor areas arranged at intervals in a first direction on a semiconductor substrate and extending in a second direction crossing the first direction, a gate insulating layer arranged on the plurality of semiconductor areas, and a charge accumulation layer arranged on the gate insulating layer;
processing the charge accumulation layer by etching and forming the charge accumulation layer of a shape in which a width change where a width of the first direction decreases monotonously, increases thereafter, and decreases again, upward from the gate insulating layer, is repeated one time or more;
forming an inter-electrode insulating layer to cover the charge accumulation layer from a predetermined surface position of the charge accumulation layer; and
forming a control electrode to cover a top surface of the inter-electrode insulating layer.

16. The method according to claim 15,
wherein the charge accumulation layer is obtained by laminating a metal layer having an etching rate higher than an etching rate of a polysilicon layer on the polysilicon layer, and
the charge accumulation layer of the shape in which the width change where the width of the first direction decreases monotonously, increases thereafter, and decreases again is repeated one time or more is formed by etching.

17. The method according to claim 15,
wherein the charge accumulation layer of a tapered shape in which the width of the first direction decreases monotonously, upward from the gate insulating layer, is formed by the etching, and
the charge accumulation layer of the shape in which the width change where the width of the first direction decreases monotonously, increases thereafter, and decreases again is repeated one time or more is formed by processing a surface portion of the charge accumulation layer not covered with an insulating layer by the etching, in a state in which a surface of a predetermined range from an uppermost portion of the charge accumulation layer is covered with the insulating layer.
